(19) United States
(12) Patent Application Publication
(10) Pub. No.: US 2026/0344355 A1
(43) Pub. Date: Oct. 29, 2026

(54) SUSCEPTOR, PLASMA PROCESSING APPARATUS, AND PLASMA PROCESSING METHOD

(71) Applicant: SwaySure Technology Co., Ltd., Shenzhen (CN)

(72) Inventor: Takayuki Fukasawa, Shenzhen (CN)

(21) Appl. No.: 19/634,646

(22) Filed: Mar. 31, 2026

(30) Foreign Application Priority Data
Apr. 28, 2025 (CN) 202510548416.5

(51) Int. Cl. H10P 72/72; H01J 37/32

(52) U.S. Cl. CPC H10P 72/722; H01J 37/32568; H01J 37/32642; H01J 37/32715; H01J 37/32834; H01J 2237/2007

(57) ABSTRACT

A susceptor for supporting a substrate in a plasma processing apparatus includes a base, a first electrode, a second electrode, and a third electrode. The first electrode is disposed in the base. The second electrode extends from a edge region of a top surface of the base to a side surface of the base. The third electrode is disposed on one side of the second electrode away from the side surface of the base. When the susceptor is used in the plasma processing apparatus, after plasma processing is completed, plasma can be formed on the surfaces of the first electrode and the second electrode. A direct-current power supply or a low-frequency alternating-current power supply connected to the third electrode charges the third electrode positively. Plasma is then formed on a surface of the third electrode.

### CROSS-REFERENCE TO RELATED APPLICATIONS

The present application claims priority to Chinese Patent Application No. 202510548416.5, filed on Apr. 28, 2025, the entire disclosure of which is hereby incorporated herein by reference.

### TECHNICAL FIELD

The present disclosure belongs to the technical field of semiconductor manufacturing equipment, and specifically relates to a susceptor, a plasma processing apparatus, and a plasma processing method.

### BACKGROUND

Plasma processing apparatuses include a plasma etching apparatus, a plasma-enhanced chemical vapor deposition apparatus, a plasma cleaning apparatus, a plasma sputtering apparatus, and a plasma ashing apparatus.

A vacuum or low-pressure environment is formed in the reaction chamber of the plasma processing apparatus, making it easy for dust particles from ambient air to enter the reaction chamber and become sources of contamination. During use of the plasma processing apparatus, the peeling of reaction residues from the inner wall surface of the reaction chamber leads to the accumulation of dust particles. In addition, during plasma processing, dust particles can also be generated through the mixing and reaction of process gases.

During plasma processing, dust particles are negatively charged by the plasma and suspended by the balance between electric field force and gravity. However, the electric field force disappears at the end of plasma processing, causing the dust particles to fall onto the substrate under gravity. This results in severe defects in subsequent processes and reduces product yield.

### SUMMARY

The present disclosure provides a susceptor for supporting a substrate in a plasma processing apparatus, the susceptor including:
a base, having a top surface and a side surface, where the top surface of the base includes a support region for supporting the substrate and an edge region surrounding the support region;
a first electrode, disposed in the base and corresponding to the support region;
a second electrode, extending from the edge region to the side surface of the base, where the second electrode is insulated from the first electrode; and
a third electrode, disposed on one side of the second electrode away from the side surface of the base, where the third electrode is insulated from the second electrode.

The present disclosure further provides a plasma processing apparatus, including: a reaction chamber; and
a susceptor for supporting a substrate in a plasma processing apparatus, comprising:
a base, having a top surface and a side surface, wherein the top surface of the base comprises a support region for supporting the substrate and an edge region surrounding the support region;
a first electrode, disposed in the base and corresponding to the support region;
a second electrode, extending from the edge region to the side surface of the base, wherein the second electrode is insulated from the first electrode; and
a third electrode, disposed on one side of the second electrode away from the side surface of the base, wherein the third electrode is insulated from the second electrode;
where the susceptor, disposed in the reaction chamber.

The present disclosure further provides a plasma processing method, applied to a plasma processing apparatus, where the plasma processing apparatus comprises:
a reaction chamber; and
a susceptor for supporting a substrate in a plasma processing apparatus, comprising:
a base, having a top surface and a side surface, wherein the top surface of the base comprises a support region for supporting the substrate and an edge region surrounding the support region;
a first electrode, disposed in the base and corresponding to the support region;
a second electrode, extending from the edge region to the side surface of the base, wherein the second electrode is insulated from the first electrode; and
a third electrode, disposed on one side of the second electrode away from the side surface of the base, wherein the third electrode is insulated from the second electrode;
where the susceptor is disposed in the reaction chamber
where the method includes:
S21: using a susceptor to support a substrate, and generating plasma in a reaction chamber to perform plasma processing on the substrate;
S22: after completing the plasma processing, maintaining the plasma in the reaction chamber, forming plasma on a side surface of the susceptor, and providing an adsorption electrode applied with a positive voltage at a bottom of the side surface of the susceptor;
S23: performing a top-down purge to weaken the plasma in the reaction chamber until the plasma is extinguished, while maintaining the plasma on the side surface of the susceptor, and maintaining the positive voltage on the adsorption electrode; and
S24: stopping the formation of the plasma on the side surface of the susceptor, applying a radio-frequency voltage to the adsorption electrode to form plasma on a surface of the adsorption electrode, maintaining the plasma on the surface of the adsorption electrode for a period of time, and maintaining the top-down purge during the period of time.

The susceptor, the plasma processing apparatus, and the plasma processing method disclosed in the present disclosure have the following beneficial effects:

Other characteristics and advantages of the present disclosure will become apparent from the following detailed description, or may be learned in part through the practice of the present disclosure.

It should be understood that the above-mentioned general description and the following detailed description are merely exemplary and explanatory, and do not limit the present disclosure.

### BRIEF DESCRIPTION OF THE DRAWINGS

The accompanying drawings herein are incorporated into the specification to constitute a part of this specification, show the embodiments in accordance with the present disclosure, and are used together with the specification to explain the principle of the present disclosure. It is clear that the accompanying drawings described below show only some embodiments of the present disclosure, and those of ordinary skill in the art may further derive other accompanying drawings from these accompanying drawings without creative efforts.

FIG. 1 is a schematic structural diagram of a susceptor in an embodiment of the present disclosure.

FIG. 2 is a schematic structural diagram of a plasma processing apparatus in an embodiment of the present disclosure.

FIG. 3 is a schematic diagram of performing plasma processing on a substrate in an embodiment of the present disclosure.

FIG. 4 is a schematic diagram of activating a second electrode in an embodiment of the present disclosure.

FIG. 5 is a schematic diagram of deactivating a first electrode in an embodiment of the present disclosure.

FIG. 6 is a schematic diagram of discharging dust particles in an embodiment of the present disclosure.

FIG. 7 is a schematic flowchart of a plasma processing method in an embodiment of the present disclosure.

FIG. 8 is a schematic structural diagram of an inductively coupled plasma device in an embodiment of the present disclosure.

FIG. 9 is a schematic structural diagram of a capacitively coupled plasma device in a n embodiment of the present disclosure.

FIG. 10 is a schematic structural diagram of a microwave plasma device in an embodiment of the present disclosure.

FIG. 11 is a control schematic diagram of a controller in an embodiment of the present disclosure.

FIG. 12 is a structural schematic diagram of connection between a third electrode and a low-frequency alternating-current power supply in an embodiment of the present disclosure.

### DETAILED DESCRIPTION OF THE EMBODIMENTS

The exemplary embodiments will now be described more fully with reference to the accompanying drawings. However, the exemplary embodiments can be implemented in various forms and should not be understood as being limited to the examples described herein; instead, these embodiments are provided to make the present disclosure more comprehensive and complete, and the concepts of the exemplary embodiments are fully conveyed to those skilled in the art.

In addition, the features, structures, or characteristics described may be combined in one or more embodiments in any suitable manner. In the following description, numerous specific details are provided to give a thorough understanding of the embodiments of the present disclosure. However, those skilled in the art will recognize that the technical solutions of the present disclosure may be practiced without one or more of the specific details, or other methods, components, devices, steps, etc. may be employed. In other cases, well-known methods, devices, implementations, or operations are not shown or described in detail to avoid obscuring aspects of the present disclosure.

The present disclosure is further described in detail below with reference to the accompanying drawings and specific embodiments. It should be noted that the technical features involved in the various embodiments of the present disclosure described below may be combined with each other as long as they do not conflict. The embodiments described below with reference to the accompanying drawings are exemplary and only intended to explain the present disclosure, and cannot be construed as a limitation on the present disclosure.

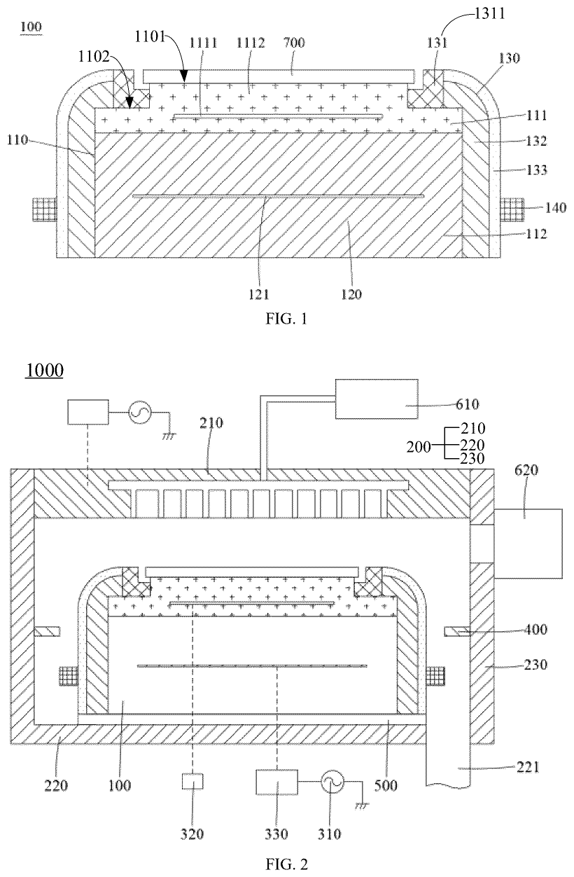

Referring to FIG. 1 and FIG. 2, in this embodiment, a susceptor 100 is configured to support a substrate 700 in a plasma processing apparatus 1000. The susceptor 100 includes a base 110, a first electrode 120, a second electrode 130, and a third electrode 140. The base 110 has a top surface and a side surface, where the top surface of the base 110 includes a support region 1101 for supporting the substrate 700 and an edge region 1102 surrounding the support region 1101.

The first electrode 120 is disposed in the base 110 and corresponds to the support region 1101. The second electrode 130 extends from the edge region 1102 to the side surface of the base 110 and is insulated from the first electrode 120. The third electrode 140 is disposed on one side of the second electrode 130 away from the side surface of the base 110 and insulated from the second electrode 130. That is, a portion of the second electrode 130 extending to the side surface of the base 110 is located between the side surface of the base 110 and the third electrode 140.

The plasma processing apparatus 1000 includes the susceptor 100 and a reaction chamber 200, where the susceptor 100 is disposed in the reaction chamber 200. A direction in which the top surface and a bottom surface of the base 110 are opposite to each other is defined as a vertical direction, and an inward-to-outward direction of the side surface of the base 110 is defined as a horizontal direction. A space for processing first plasma P1 is formed between the first electrode 120 and the reaction chamber 200, a space for processing second plasma P2 is formed between a combination of the first electrode 120 and the second electrode 130 and the reaction chamber 200, and a space for processing third plasma P3 is formed between the third electrode 140 and the reaction chamber 200.

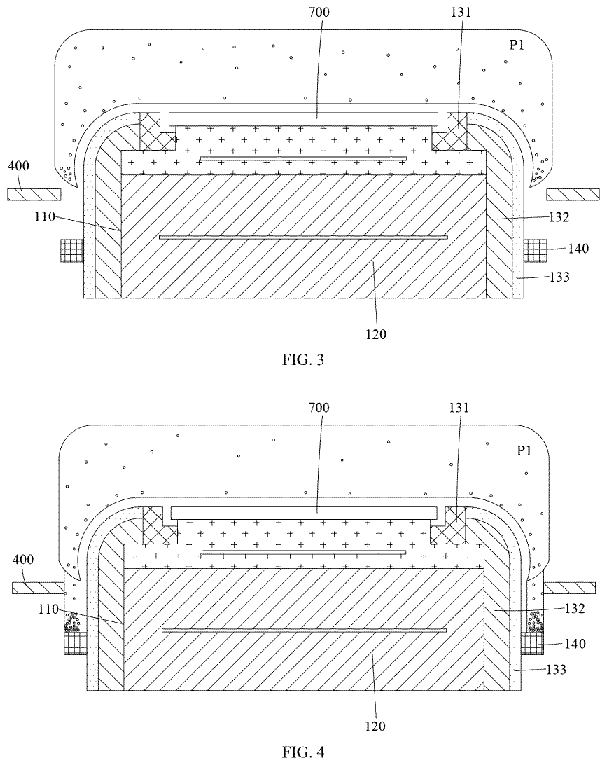

In a first stage, during plasma processing, the first plasma is formed between the first electrode 120 and a wall of the reaction chamber 200, and negatively charged particles accumulate in a presheath between an ion sheath and the plasma, and do not fall onto the substrate 700, as shown in FIG. 3.

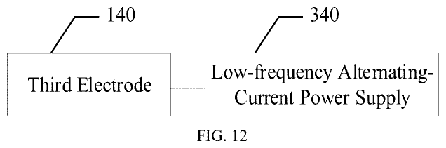

In a second stage, after the plasma processing is completed, a radio-frequency power supply 310 connected to the first electrode 120 continues to supply power, a radio-frequency power supply 310 connected to the second electrode 130 begins to supply power, the plasma is formed on both a surface of the first electrode 120 and a surface of the second electrode 130, and a direct-current power supply 320 or a low-frequency alternating-current power supply 340 connected to the third electrode 140 charges the third electrode 140 positively to attract negatively charged dust particles, as shown in FIGS. 2, 4, and 12.

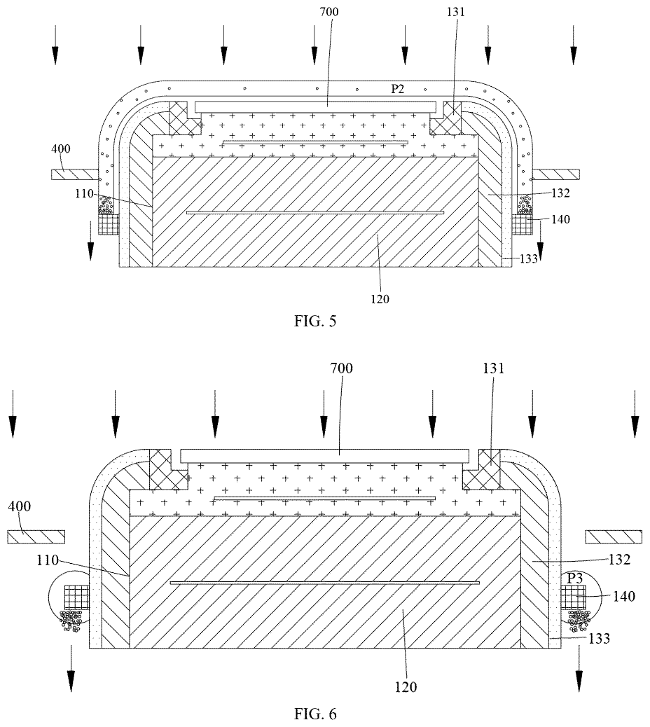

In a third stage, the power output to the first electrode 120 is reduced to zero (e.g., the power output to the first electrode 120 is gradually reduced, such that the power to the first electrode 120 is zero at the end of the third stage). During the process of reducing the power, the dust particles can be gradually attracted to the third electrode 140, in which case the plasma is P2, as shown in FIG. 5. After the attraction is completed, the plasma maintained by the first electrode 120 can be extinguished.

In a fourth stage, power supply to the first electrode 120 and the second electrode 130 and power supply from the direct-current power supply 320 or the low-frequency alternating-current power supply 340 connected to the third electrode 140 are stopped, the radio-frequency power supply 310 connected to the third electrode 140 starts to supply power, and the plasma P3 is formed on a surface of the third electrode 140 to discharge the dust particles adsorbed on the surface of the third electrode 140, as shown in FIG. 6.

It should be noted that the width of the plasma in FIGS. 3 to 6 represents a plasma density, rather than an actual boundary of the plasma.

During plasma processing, the dust particles are negatively charged by the plasma and suspended by the balance between electric field force and gravity. In the related art, after the plasma processing is completed, a plasma generation device 1100 stops operating, the electric field force disappears, and the dust particles fall onto the substrate 700 under the gravity, thereby causing serious defects in subsequent processes and reducing product yield.

In this embodiment, the susceptor 100 includes the base 110, the first electrode 120, the second electrode 130, and the third electrode 140, where the base 110 has the top surface and the side surface, the top surface of the base 110 includes the support region 1101 for supporting the substrate 700 and the edge region 1102 surrounding the support region 1101, the first electrode 120 is disposed in the base 110, the second electrode 130 extends from the edge region 1102 to the side surface of the base 110, and the third electrode 140 is disposed on one side of the second electrode 130 away from the side surface of the base 110. When the susceptor 100 is used in the plasma processing apparatus 1000, after the plasma processing is completed, the plasma can be formed on the surfaces of the first electrode 120 and the second electrode 130 to prevent the dust particles from falling onto the substrate 700. The direct-current power supply 320 or the low-frequency alternating-current power supply 340 connected to the third electrode 140 charges the third electrode 140 positively to attract the negatively charged dust particles. The plasma is then formed on the surface of the third electrode 140 to discharge the dust particles adsorbed on the surface of the third electrode 140, thereby reducing the risk of the dust particles falling onto the substrate 700 and improving the product yield.

In some embodiments, the base 110 includes an electrostatic chuck 111 and a support table 112, where the electrostatic chuck 111 is disposed on a top surface of the support table 112, the top surface of the base 110 is a top surface of the electrostatic chuck 111, and the side surface of the base 110 includes a side surface of the electrostatic chuck 111 and a side surface of the support table 112.

The electrostatic chuck 111 may include a ceramic body 1111 and an electrostatic electrode 1112, where the electrostatic electrode 1112 is embedded in the ceramic body 1111. The electrostatic electrode 1112 may be connected to the direct-current power supply 320, and generates electrostatic force by a direct-current voltage applied from the direct-current power supply 320 to the electrostatic electrode 1112, thereby adsorbing the substrate 700 in the support region 1101 of the electrostatic chuck 111.

The support table 112 is approximately cylindrical in shape. The ceramic body 1111 is disposed on the support table 112 and is cylindrical as a whole. The support region 1101 and the edge region 1102 are located on the same horizontal plane. Additionally, the ceramic body 1111 may also include an upper cylindrical portion and a lower cylindrical portion that are stacked, where the upper cylindrical portion has a smaller diameter than the lower cylindrical portion, the support region 1101 is a top surface of the upper cylindrical portion, and the edge region 1102 is part of a top surface of the lower cylindrical portion.

The base 110 includes the electrostatic chuck 111 and the support table 112, where the electrostatic chuck 111 can adsorb the substrate 700 by the electrostatic force, thereby preventing the substrate 700 from shifting during plasma processing.

In some embodiments, the first electrode 120 includes a first conductive electrode 121, where the first conductive electrode 121 may be disposed in the support table 112 or the ceramic body 1111; and the first electrode 120 includes the support table 112 or the electrostatic chuck 111. Additionally, the support table 112 may be made of a conductive or semiconductor material and connected to the radio-frequency power supply 310, serving as the first electrode 120.

The first electrode 120 includes the support table 112 or the electrostatic chuck 111. The space for processing the first plasma may be formed between the first electrode 120 and the reaction chamber 200 to perform plasma processing on the substrate 700, where the plasma processing includes plasma etching, plasma-enhanced chemical vapor deposition, plasma cleaning, plasma sputtering, and plasma ashing.

In some embodiments, the second electrode 130 includes a second upper electrode 131 located in the edge region 1102 and a second lower electrode 132 extending from one side of the second upper electrode 131 away from the support region 1101 to the side surface of the base 110, where the second upper electrode 131 is electrically or insulatively connected to the second lower electrode 132. The second upper electrode 131 is disposed around the electrostatic chuck 111, and the second lower electrode 132 is disposed around the electrostatic chuck 111 and the support table 112.

The second electrode 130 includes the second upper electrode 131 and the second lower electrode 132, where the same or different voltages may be applied to the second upper electrode 131 and the second lower electrode 132 as needed. For example, during and after plasma processing of the substrate 700, different voltages may be applied to the second upper electrode 131 and the second lower electrode 132; and after plasma processing of the substrate 700, the same or different voltages may be applied to the second upper electrode 131 and the second lower electrode 132 as needed.

In some embodiments, the second upper electrode 131 includes a focus ring 1311, where the focus ring 1311 is an annular structural member surrounding the first electrode 120, and the focus ring 1311 may be floating or connected to a power supply. The floating focus ring 1311 has a simple structure, and does not require additional power supply connections or complex circuit design, thereby reducing equipment cost and complexity. After the focus ring 1311 is connected to the power supply, an electric field distribution around the focus ring 1311 can be changed by adjusting a voltage supplied by the power supply, thereby more precisely controlling a motion trajectory and distribution of ions in the plasma.

During plasma processing of the substrate 700, the second upper electrode 131 serves as the focus ring 1311 to control the electric field distribution, the ion motion trajectory, and a plasma density distribution, such that the uniformity of plasma distribution is improved, thus enhancing the process consistency of plasma processing. After plasma processing of the substrate 700, the plasma can be generated on the surfaces of the second upper electrode 131 and the second lower electrode 132 to prevent the dust particles from falling and to discharge the dust particles.

In some embodiments, the connection between the second upper electrode 131 and the second lower electrode 132 includes an electrical connection between the second lower electrode 132 and the second upper electrode 131.

When the second upper electrode 131 is electrically connected to the second lower electrode 132, the radio-frequency power supply 310 may be connected to either the second upper electrode 131 or the second lower electrode 132, such that the plasma can be generated on the surfaces of both the second upper electrode 131 and the second lower electrode 132.

In some embodiments, the second upper electrode 131 and the second lower electrode 132 are insulatively connected. The second upper electrode 131 is made of a material including silicon (Si), glassy carbon, quartz, and aluminum (Al). When the second upper electrode 131 is made of a semiconductor material or a conductive material, the second electrode 130 may further include a first insulating layer, where the first insulating layer is formed on an outer surface of the second upper electrode 131, and the first insulating layer is made of a material including aluminum oxide (Al₂O₃), silicon dioxide (SiO₂), or yttrium oxide (Y₂O₃). When the second upper electrode 131 is made of an insulating material, the first insulating layer may be omitted.

It should be noted that when the second upper electrode 131 is made of the conductive or semiconductor material and has the first insulating layer formed on the surface thereof, the second upper electrode 131 may be loaded with the radio-frequency power supply to form the plasma on the surface thereof in the second and third stages, or the second upper electrode 131 may be floating; and when the second upper electrode 131 is made of the insulating material, since the first electrode 120 and the second lower electrode 132 are both loaded with the radio-frequency power supply to generate the plasma in the second and third stages, the plasma on the surfaces of the first electrode 120 and the second lower electrode 132 can be formed continuously, and the negatively charged dust particles are still confined in the presheath and cannot fall onto a surface of a wafer. That is, although the second upper electrode 131 is referred to as an “electrode”, it may still be made of the insulating material. The second upper electrode 131 may be the focus ring 1311 made of the insulating material.

The second lower electrode 132 is made of a material including doped silicon, glassy carbon, and aluminum. The second lower electrode 132 is made of the same material as or a different material from the second upper electrode 131. The second electrode 130 may further include a second insulating layer 133, where the second insulating layer 133 is formed on an outer surface of the second lower electrode 132, and the second lower electrode 132 and the second upper electrode 131 are insulatively connected via the second insulating layer 133. The second insulating layer 133 is made of a material including aluminum oxide, silicon dioxide, or yttrium oxide. The second lower electrode 132 is made of a conductive material including, but not limited to, glassy carbon and aluminum. The second lower electrode 132 may also be made of a semiconductor material such as elemental silicon, depending on specific circumstances.

When the second upper electrode 131 is insulatively connected to the second lower electrode 132, the radio-frequency power supply 310 may be connected to the second lower electrode 132. Since the plasma can be generated on the surfaces of the first electrode 120 and the second lower electrode 132, the plasma can be maintained on the second upper electrode 131 even without applying voltage. In this case, the second upper electrode 131 may be insulating, or the second upper electrode 131 is insulating with its surface covered by the first insulating layer and the second upper electrode 131 is floating.

In some embodiments, the third electrode 140 is made of a material including doped silicon. The third electrode 140 is connected to the direct-current power supply 320 or the low-frequency alternating-current power supply 340 to charge the third electrode 140 positively. In other embodiments, the third electrode 140 includes a third conductive electrode and a third insulating layer, where the third insulating layer is formed on an outer surface of the third conductive electrode. The third conductive electrode is made of a material including glassy carbon and aluminum, and the third insulating layer is made of a material including aluminum oxide, silicon dioxide, or yttrium oxide.

Even if the third insulating layer is formed on the outer surface of the third conductive electrode, the third electrode 140 may still be positively charged by the low-frequency alternating-current power supply 340, without affecting the adsorption of the dust particles by the third electrode 140. The third insulating layer can be formed on the surface of the third conductive electrode to protect the third conductive electrode. The third insulating layer is made of a material with high temperature resistance and good stability, which can prevent the third electrode 140 from becoming a source of contamination.

It should be noted that the third electrode 140 is positively charged to attract the negatively charged dust particles, i.e., the positive voltage applied thereto is sufficient to cause negatively charged ions to break free from the confinement of the presheath. It should also be noted that when the low-frequency alternating-current power supply 340 is applied to the third electrode 140, the positive voltage may be an average value of the alternating-current power supply.

In some embodiments, the third electrode 140 is insulated from the second electrode 130. For example, a gap is formed between the third electrode 140 and the second electrode 130, such that the third electrode 140 is insulated from the second electrode 130. In other embodiments, the third electrode 140 is insulatively connected to the second electrode 130 via an insulating layer, where the insulating layer is the second insulating layer 133 or the third insulating layer. The thickness of the insulating layer between the third electrode 140 and the second electrode 130 is required to be sufficient to isolate a high-frequency alternating current. For example, the thickness of the insulating layer between the third electrode 140 and the second electrode 130 is greater than 50μm.

The third electrode 140 is insulatively connected to the second electrode 130 via the insulating layer, and the third electrode 140 and the second electrode 130 are integrally connected. When the susceptor 100 is used in the plasma processing apparatus 1000, a mounting and fixing structure for the third electrode 140 may be omitted or simplified, thereby helping to reduce the manufacturing cost of the plasma processing apparatus 1000.

In some embodiments, an outer surface of the second electrode 130 located at a corner between the top surface of the base 110 and the side surface of the base 110 is an arc surface. The arc surface has a curvature of 2 cm to 10 cm, for example, the curvature of the arc surface is 2 cm, 5 cm, or 10 cm. The second upper electrode 131 is disposed around the electrostatic chuck 111, and has a width of 5 mm to 5 cm in a radial direction. Preferably, the width of the second upper electrode 131 in the radial direction is 1 cm to 3 cm.

The outer surface of the second electrode 130 located at the corner between the top surface of the base 110 and the side surface of the base 110 is the arc surface, such that the second electrode 130 does not block the dust particles from moving toward the third electrode 140.

The present disclosure further provides a plasma processing apparatus 1000, including the above-disclosed susceptor 100 and a reaction chamber 200, where the susceptor 100 is disposed in the reaction chamber 200. The reaction chamber 200 may be a cylindrical container made of anodized aluminum. The reaction chamber 200 may include a top plate 210 and a bottom plate 220 disposed oppositely in the vertical direction, and a side plate 230 that surrounds and is connected to the top plate 210 and the bottom plate 220. The susceptor 100 may be disposed on the bottom plate 220 via an insulating plate 500. The side plate 230 is further provided with a gate valve 620. The substrate 700 can be transferred into or out of the reaction chamber 200 via the gate valve 620.

When the susceptor 100 is used in the plasma processing apparatus 1000, after the plasma processing is completed, the plasma can be formed on the surfaces of the first electrode 120 and the second electrode 130 to prevent the dust particles from falling onto the substrate 700. The direct-current power supply 320 or the low-frequency alternating-current power supply 340 connected to the third electrode 140 charges the third electrode 140 positively to attract the negatively charged dust particles. The plasma is then formed on the surface of the third electrode 140 to discharge the dust particles adsorbed on the surface of the third electrode 140, thereby reducing the risk of the dust particles falling onto the substrate 700 and improving the product yield.

In some embodiments, the plasma processing apparatus 1000 further includes a baffle 400, where the baffle 400 is disposed between the reaction chamber 200 and the side surface of the base 110, spaced apart from the susceptor 100, and connected to an inner wall of the side plate 230, and the third electrode 140 is located on one side of the baffle 400 away from the support region 1101. The baffle 400 may be an anodized aluminum structural member.

The third electrode 140 is disposed on one side of the baffle 400 away from the support region 1101. When the plasma is formed on the surface of the third electrode 140 to discharge the dust particles adsorbed on the surface of the third electrode 140, the baffle 400 can block the dust particles from returning above the baffle 400 and falling onto the substrate 700.

When the plasma is formed on the surface of the second electrode 130, the plasma passes between the baffle 400 and the second electrode 130.

In some embodiments, a distance between the third electrode 140 and the baffle 400 in the vertical direction is greater than 1 cm. For example, the distance between the third electrode 140 and the baffle 400 in the vertical direction is 1 cm to 2 cm. Preferably, the distance between the third electrode 140 and the baffle 400 in the vertical direction is 3 cm to 5 cm or greater than 5 cm.

A sufficient gap is formed between the third electrode 140 and the baffle 400 to prevent the dust particles from returning above the baffle 400 and falling onto the substrate 700.

In some embodiments, the plasma processing apparatus 1000 further includes a plasma generation device 1100, where the plasma generation device 1100 includes an inductively coupled plasma (ICP) device, a capacitively coupled plasma (CCP) device, and a microwave plasma (MP) device. The specific structure of the plasma generation device 1100 is not limited in this disclosure.

It can be understood that the plasma generation device 1100 is a set of components used in conjunction with the first electrode 120 to generate, in the chamber, the plasma for performing plasma processing on the substrate in the first stage. For example, in an embodiment where the plasma generation device 1100 includes an ICP device, the plasma generation device 1100 includes an inductive coil wound outside the reaction chamber 200 and a radio-frequency power supply connected to the inductive coil.

The susceptor 100 may be used in various types of plasma processing apparatus 1000es, thereby improving the versatility of the component.

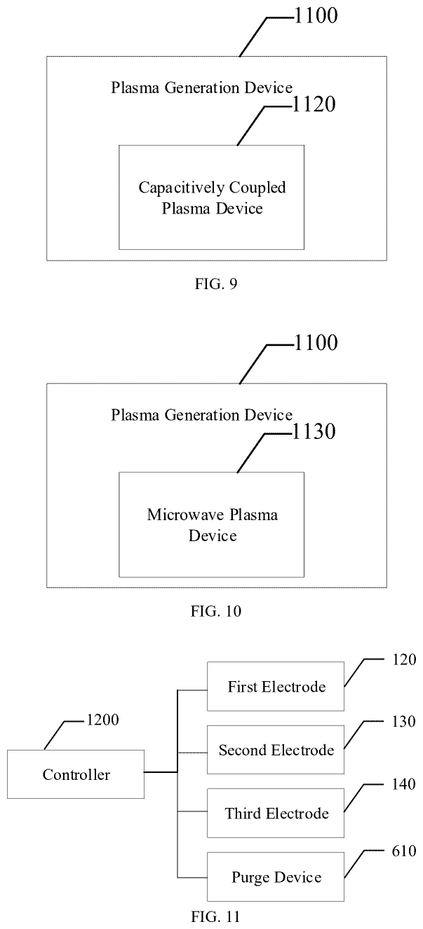

In some embodiments, both the first electrode 120 and the second electrode 130 are connected to the radio-frequency power supply 310 via a matcher 330. The radio-frequency power supply 310 connected to the first electrode 120 has a frequency of 100 kHz to 13.56 MHz, and the radio-frequency power supply 310 connected to the second electrode 130 has a frequency of 100 kHz to 13.56 MHz. Taking the plasma generation device 1100 that is a capacitively coupled plasma device as an example, the top plate 210 may be connected to a radio-frequency power supply 310 via a matcher 330. The frequency of the radio-frequency power supply 310 connected to the top plate 210 may be 27 MHz to 100 MHz. The side plate 230 of the reaction chamber 200 may be grounded. Referring to FIGS. 8-10, in some embodiments, the plasma generation device 1100 comprises one of an inductively coupled plasma device 1110, a capacitively coupled plasma device 1120, or a microwave plasma device 1130.

The first electrode 120 and the second electrode 130 are connected to the radio frequency power supplies 310 of the same frequency. The plasma formed by the first electrode 120 is used to process the substrate 700. After the plasma processing is completed, the plasma formed by the second electrode 130 is used to transfer the dust particles and prevent them from falling onto the substrate 700. The power required to maintain the plasma on the surface of the second electrode 130 is lower than that required to maintain the plasma on the surface of the first electrode 120. The first electrode 120 and the second electrode 130 may share a single radio-frequency power supply 310, and a small amount of power is distributed to the second electrode 130 using a power divider.

In some embodiments, the second electrode 130 includes a second upper electrode 131 and a second lower electrode 132, where the second upper electrode 131 is electrically or insulatively connected to the second lower electrode 132. At least the second lower electrode 132 is connected to the radio-frequency power supply 310. That is, the second lower electrode 132 is connected to the radio-frequency power supply 310, and the second upper electrode 131 may be floating, connected to the radio-frequency power supply 310, or connected to another direct-current power supply 320 or alternating-current power supply.

Since the plasma can be generated on the surfaces of both the first electrode 120 and the second lower electrode 132, the plasma can be continuously maintained on the second upper electrode 131 even without applying voltage. During plasma processing of the substrate 700, the second upper electrode 131 serves as the focus ring 1311 and may be either floating or connected to a power supply as needed to improve the uniformity of plasma distribution and thus enhance the process consistency of plasma processing.

In some embodiments, the third electrode 140 is connected to the radio-frequency power supply 310 and one of the low-frequency alternating-current power supply 340 and the direct-current power supply 320, where the direct-current power supply 320 and the low-frequency alternating-current power supply 340 can provide a positive voltage, and the frequency of the low-frequency alternating-current power supply 340 is lower than that of the radio-frequency power supply 310.

When the plasma is formed on the surface of the third electrode 140, the dust particles adsorbed on the surface of the third electrode 140 can be discharged. Since the plasma formed on the surface of the third electrode 140 is only used to move the dust particles away from the third electrode 140, the third electrode 140 may share a single radio-frequency power supply 310 with the first electrode 120, and a small amount of power is distributed to the third electrode 140 using the power divider.

When the third electrode 140 is positively charged to attract the negatively charged dust particles, the third electrode 140 is connected to the direct-current power supply 320 and the low-frequency alternating-current power supply 340, where the frequency of the low-frequency alternating-current power supply 340 is 50 Hz to 100 kHz, preferably 50 Hz to 1 kHz, that is, the low-frequency alternating-current power supply 340 charges the third electrode 140 positively without forming the plasma on the surface of the third electrode 140.

The first plasma is formed between the first electrode 120 and the reaction chamber 200. Electrons, due to their light mass, can easily move following changes in an electric field, whereas the ions, whose mass is approximately 100,000 times that of the electrons, cannot move promptly with the frequency of the radio-frequency power supply 310. As a result, the electrons gradually accumulate on the first electrode 120, such that the first electrode 120 is gradually biased to a negative potential, thereby forming a direct-current bias Vdc, where the magnitude of the direct-current bias Vdc depends at least on the power of the radio-frequency power supply 310. When the third electrode 140 is positively charged to attract the negatively charged dust particles, the positive voltage is greater than the direct-current bias Vdc formed by the first plasma and the direct-current bias Vdc formed by the second plasma, thereby preventing the negatively charged dust particles from being confined in the presheath and improving the efficiency with which the positively charged third electrode 140 attracts the negatively charged dust particles.

In some embodiments, the plasma processing apparatus 1000 further includes a purge device 610, where the purge device 610 is configured to provide a purge gas to perform a purge from a top of the susceptor 100 to a bottom of the susceptor. The purge device 610 may be connected to the top plate 210, and the purge gas is blown from the top of the susceptor 100 to the bottom of the susceptor via the top plate 210. At least one exhaust port 221 may be formed in a region of the bottom plate 220 around the susceptor 100.

The purge device can provide a purge gas flow to move the dust particles toward the third electrode 140 in the third and fourth stages.

During plasma processing of the substrate 700, the purge gas pressure is p1 and the exhaust speed is V1. When the third electrode 140 is positively charged to attract the negatively charged dust particles, the purge gas pressure can be increased to p2 and the exhaust speed can be increased to V2, such that the dust particles move along the presheath formed by the second plasma toward the third electrode 140 and are adsorbed onto the third electrode 140. When the plasma is formed on the surface of the third electrode 140 to move the dust particles away from the third electrode 140, the purge gas pressure p2 and the exhaust speed V2 can be maintained, such that the dust particles are discharged from the reaction chamber 200 along with the purge gas flow.

In some embodiments, as shown in FIG. 11, the plasma processing apparatus 1000 further includes a controller 1200, where the controller 1200 is capable of controlling at least the first electrode 120, the second electrode 130, the third electrode 140, and the purge device 610 to perform the following operations.

In S11, plasma processing is performed, where the second electrode 130 and the third electrode 140 are floating.

As shown in FIG. 3, the first plasma is formed between the first electrode 120 and the reaction chamber 200 to perform plasma processing on the substrate 700, the negatively charged particles accumulate in the presheath between the ion sheath and the plasma, and do not fall onto the substrate 700, and the second electrode 130 and the third electrode 140 are floating.

In S12, the first electrode 120 is connected to the radio-frequency power supply 310 to maintain plasma in the reaction chamber 200, the second upper electrode 131 is floating or connected to the radio-frequency power supply 310, the second lower electrode 132 is connected to the radio-frequency power supply 310 to form the plasma on the surface of the second electrode 130, and the third electrode 140 is connected to the positive voltage.

As shown in FIG. 4, after the plasma processing is completed, the radio-frequency power supply 310 connected to the first electrode 120 continues to supply power, the second upper electrode 131 is floating or connected to the radio-frequency power supply 310, and the second lower electrode 132 is connected to the radio-frequency power supply 310 to form the plasma on the surface of the second electrode 130, which prevents the dust particles from falling onto the substrate 700 or the second electrode 130; and the direct-current power supply 320 or the low-frequency alternating-current power supply 340 connected to the third electrode 140 charges the third electrode 140 positively to attract the negatively charged dust particles.

In S13, the power of the radio-frequency power supply 310 connected to the first electrode 120 is reduced to zero, both the second upper electrode 131 and the second lower electrode 132 are connected to the radio-frequency power supply 310 to form the plasma on the surface of the second electrode 130, the third electrode 140 is connected to the positive voltage, and the purge device 610 provides the purge gas to perform a gas flow purge from above the susceptor 100 to below the susceptor.

Optionally, in step S12, the purge gas is also provided to perform the gas flow purge from above the susceptor 100 to below the susceptor, and in step S13, both the pressure and the flow velocity of the purge gas are higher than those in step S12.

As shown in FIG. 5, the power output to the first electrode 120 is reduced to zero (e.g., the power is zero at the end of step S13, or step S13 further includes a stage after the power output to the first electrode 120 is reduced to zero). Both the second upper electrode 131 and the second lower electrode 132 are connected to the radio-frequency power supply 310 to form the plasma on the surface of the second electrode 130, thereby preventing the dust particles from falling onto the substrate 700 or the second electrode 130. The direct-current power supply 320 or the low-frequency alternating-current power supply 340 connected to the third electrode 140 charges the third electrode 140 positively to attract the negatively charged dust particles. The dust particles move toward the third electrode 140 along with the purge gas flow and are adsorbed onto the third electrode 140.

In S14, the first electrode 120 and the second electrode 130 are grounded or floating, the third electrode 140 is connected to the radio-frequency power supply 310 to form the plasma on the surface of the third electrode 140, the plasma formed on the surface of the third electrode 140 is maintained for a period of time, and the purge is maintained during the period of time.

As shown in FIG. 6, power supply to the first electrode 120 and the second electrode 130 and power supply from the direct-current power supply 320 or the low-frequency alternating-current power supply 340 connected to the third electrode 140 are stopped, the radio-frequency power supply 310 connected to the third electrode 140 starts to supply power, and the plasma is formed on the surface of the third electrode 140, such that the dust particles adsorbed on the surface of the third electrode 140 are recharged negatively, thereby being confined in the presheath, moving away from the third electrode 140, and being discharged out of the reaction chamber 200 along with the purge gas flow.

After the plasma processing is completed, the dust particles are first adsorbed onto the third electrode 140, and the plasma is then formed on the surface of the third electrode 140 to discharge the dust particles adsorbed on the surface of the third electrode 140, thereby reducing the risk of the dust particles falling onto the substrate 700 and improving the product yield.

Optionally, after a period of time, the top-down purge is stopped.

It can be understood that after step S11, the plasma processing of the substrate has been completed, but the plasma still needs to be formed. Therefore, in steps S12 to S14, i.e., in the aforementioned second to fourth stages and the subsequent steps S22 to S24, the introduction of a process gas into the reaction chamber 200 is stopped, and an inert gas is introduced. The plasma is maintained by the radio-frequency voltage applied to the first electrode 120.

Optionally, in steps S12 to S14, or the second to fourth stages, or the subsequent steps S22 to S24, the gas pressure in the reaction chamber 200 may also be increased during the introduction of the inert gas. Optionally, in steps S13 and S14, the third to fourth stages, or the subsequent steps S23 and S24, the plasma density is lower than that during plasma processing of the substrate.

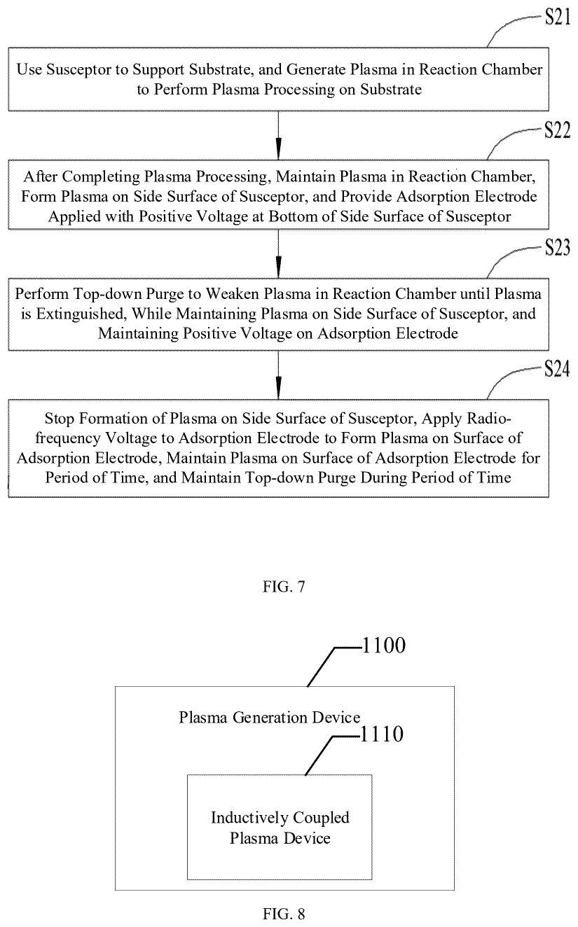

The present disclosure further provides a plasma processing method. Referring to FIG. 7, the plasma processing method includes:
S21: using a susceptor 100 to support a substrate 700, and generating plasma in a reaction chamber 200 to perform plasma processing on the substrate 700;
S22: after completing the plasma processing, maintaining the plasma in the reaction chamber 200, forming plasma on a side surface of the susceptor 100, and providing an adsorption electrode applied with a positive voltage at a bottom of the side surface of the susceptor 100;
S23: performing a top-down purge to weaken the plasma in the reaction chamber 200 until the plasma is extinguished, while maintaining the plasma on the side surface of the susceptor 100, and maintaining the positive voltage on the adsorption electrode; and
S24: stopping the formation of the plasma on the side surface of the susceptor 100, applying a radio-frequency voltage to the adsorption electrode to form plasma on a surface of the adsorption electrode, maintaining the plasma on the surface of the adsorption electrode for a period of time, and maintaining the top-down purge during the period of time.

Optionally, after a period of time, the top-down purge is stopped.

It can be understood that the plasma in the reaction chamber 200 refers to the plasma above the substrate 700.

After the plasma processing is completed, the first electrode 120 is used to maintain the plasma in the reaction chamber 200. The plasma is formed on the side surface of the susceptor 100. The negatively charged dust particles accumulate in the presheath between the ion sheath and the plasma, and do not fall onto the substrate 700. The adsorption electrode can adsorb the dust particles, which move toward the adsorption electrode along with the purge gas flow and are adsorbed onto the adsorption electrode. Finally, the radio-frequency voltage is applied to the adsorption electrode to form the plasma on the surface of the adsorption electrode, such that the dust particles adsorbed on the adsorption electrode move away from the adsorption electrode and are discharged out of the reaction chamber 200 along with the purge gas flow. Therefore, the plasma processing method disclosed in the present disclosure can be used to discharge the dust particles from the reaction chamber 200, thereby reducing the risk of the dust particles falling onto the substrate 700 and improving the product yield.

The terms “first”, “second”, and the like are used only for descriptive purposes, and should not be construed as indicating or implying relative importance or implicitly indicating the number of technical features indicated. Thus, features defined with “first”, “second”, and the like may explicitly or implicitly include one or more of the features. In the description of the present disclosure, “a plurality of” means two or more, unless otherwise expressly and specifically defined.

In the present disclosure, the terms “assemble”, “connect”, and the like should be understood in a broad sense, unless otherwise expressly specified and limited. For example, it may be a fixed connection, a detachable connection, or an integrated connection; it may be a mechanical connection or an electrical connection; and it may be a direct connection, an indirect connection via an intermediate medium, an internal communication between two elements, or an interaction between two elements. Those of ordinary skill in the art can understand specific meanings of the above terms in this disclosure according to specific circumstances.

In the description of this specification, the description with reference to the term “some embodiments”, “by way of example”, or the like refers to that the specific features, structures, materials, or characteristics described in combination with the embodiment or example are included in at least one embodiment or example of the present disclosure. In this specification, schematic representations of the above terms need not be directed to the same embodiments or examples. Moreover, the specific features, structures, materials, or characteristics described may be combined suitably in any one or more embodiments or examples. In addition, different embodiments or examples described in this specification and features of different embodiments or examples may be connected and combined by those skilled in the art without mutual contradiction.

Although the embodiments of the present disclosure have been shown and described above, it can be understood that the above embodiments are exemplary and should not be construed as limiting the present disclosure. Those of ordinary skill in the art may make changes, modifications, substitutions, and variations to the above embodiments within the scope of the present disclosure. Therefore, any changes or modifications made in accordance with the claims and specification of the present disclosure shall fall within the scope of the present disclosure.

What is claimed is:

1. A susceptor for supporting a substrate in a plasma processing apparatus, comprising:
a base, having a top surface and a side surface, wherein the top surface of the base comprises a support region for supporting the substrate and an edge region surrounding the support region;
a first electrode, disposed in the base and corresponding to the support region;
a second electrode, extending from the edge region to the side surface of the base, wherein the second electrode is insulated from the first electrode; and
a third electrode, disposed on one side of the second electrode away from the side surface of the base, wherein the third electrode is insulated from the second electrode.

2. The susceptor according to claim 1, wherein the base comprises an electrostatic chuck and a support table, wherein the electrostatic chuck is disposed on a top surface of the support table, the top surface of the base is a top surface of the electrostatic chuck, and the side surface of the base comprises a side surface of the electrostatic chuck and a side surface of the support table.

3. The susceptor according to claim 2, wherein the first electrode comprises the support table or the electrostatic chuck.

4. The susceptor according to claim 1, wherein the second electrode comprises a second upper electrode located in the edge region and a second lower electrode extending from one side of the second upper electrode away from the support region to the side surface of the base, and the second upper electrode is connected to the second lower electrode.

5. The susceptor according to claim 4, wherein the second upper electrode comprises a focus ring.

6. The susceptor according to claim 4, wherein a connection between the second upper electrode and the second lower electrode comprises an electrical connection between the second lower electrode and the second upper electrode.

7. The susceptor according to claim 4, wherein the second electrode comprises a second insulating layer, the second insulating layer is formed on an outer surface of the second lower electrode, and the second lower electrode and the second upper electrode are insulatively connected via the second insulating layer.

8. The susceptor according to claim 1, wherein the third electrode is insulated from the second electrode comprises:
the third electrode is insulatively connected to the second electrode through a second insulating layer.

9. The susceptor according to claim 1, wherein an outer surface of the second electrode located at a corner between the top surface of the base and the side surface of the base is an arc surface.

10. The susceptor according to claim 1, wherein the third electrode is made of a material comprising silicon.

11. A plasma processing apparatus, comprising:
a reaction chamber; and
a susceptor for supporting a substrate in the plasma processing apparatus, comprising:
a base, having a top surface and a side surface, wherein the top surface of the base comprises a support region for supporting the substrate and an edge region surrounding the support region;
a first electrode, disposed in the base and corresponding to the support region;
a second electrode, extending from the edge region to the side surface of the base, wherein the second electrode is insulated from the first electrode; and
a third electrode, disposed on one side of the second electrode away from the side surface of the base, wherein the third electrode is insulated from the second electrode;
wherein the susceptor is disposed in the reaction chamber.

12. The plasma processing apparatus according to claim 11, further comprising a baffle, wherein the baffle is disposed between the reaction chamber and the side surface of the base, the baffle is spaced apart from the susceptor, and the third electrode is located on one side of the baffle away from the support region.

13. The plasma processing apparatus according to claim 12, wherein the top surface and a bottom surface of the base are opposite to each other in a vertical direction, and a distance between the third electrode and the baffle in the vertical direction is greater than 1 cm.

14. The plasma processing apparatus according to claim 11, further comprising a plasma generation device, wherein the plasma generation device comprises one of an inductively coupled plasma device, a capacitively coupled plasma device, or a microwave plasma device.

15. The plasma processing apparatus according to claim 14, wherein both the first electrode and the second electrode are connected to a radio-frequency power supply.

16. The plasma processing apparatus according to claim 15, wherein the second electrode comprises a second upper electrode located in the edge region and a second lower electrode extending from one side of the second upper electrode away from the support region to the side surface of the base, the second upper electrode is electrically or insulatively connected to the second lower electrode, and at least the second lower electrode is connected to the radio-frequency power supply.

17. The plasma processing apparatus according to claim 11, wherein the third electrode is connected to a radio-frequency power supply and one of a low-frequency alternating-current power supply or a direct-current power supply, both the direct-current power supply and the low-frequency alternating-current power supply are capable of providing a positive voltage, and the low-frequency alternating-current power supply has a lower frequency than the radio-frequency power supply.

18. The plasma processing apparatus according to claim 11, further comprising a purge device, wherein the purge device is configured to provide a purge gas to perform a purge from a top of the susceptor to a bottom of the susceptor.

19. The plasma processing apparatus according to claim 18, wherein the second electrode comprises a second upper electrode located in the edge region and a second lower electrode extending from one side of the second upper electrode away from the support region to the side surface of the base, and the second upper electrode is electrically or insulatively connected to the second lower electrode; and the plasma processing apparatus further comprises a controller, wherein the controller is capable of controlling at least the first electrode, the second electrode, the third electrode, and the purge device to perform the following operations:
S11: performing plasma processing, wherein the second electrode and the third electrode are floating;
S12: connecting the first electrode to a radio-frequency power supply to maintain plasma in the reaction chamber, floating or connecting the second upper electrode to the radio-frequency power supply, connecting the second lower electrode to the radio-frequency power supply to form plasma on a surface of the second electrode, and connecting the third electrode to a positive voltage;
S13: reducing a power of the radio-frequency power supply connected to the first electrode to zero, connecting both the second upper electrode and the second lower electrode to the radio-frequency power supply to form the plasma on the surface of the second electrode, connecting the third electrode to the positive voltage, and providing, by the purge device, the purge gas to perform a gas flow purge from above the susceptor to below the susceptor; and
S14: grounding or floating the first electrode and the second electrode, connecting the third electrode to the radio-frequency power supply to form plasma on a surface of the third electrode, maintaining the plasma formed on the surface of the third electrode for a period of time, and maintaining the purge during the period of time.

20. A plasma processing method, applied to a plasma processing apparatus, wherein the plasma processing apparatus comprises:
a reaction chamber; and
a susceptor for supporting a substrate in the plasma processing apparatus, comprising:
a base, having a top surface and a side surface, wherein the top surface of the base comprises a support region for supporting the substrate and an edge region surrounding the support region;
a first electrode, disposed in the base and corresponding to the support region;
a second electrode, extending from the edge region to the side surface of the base, wherein the second electrode is insulated from the first electrode; and
a third electrode, disposed on one side of the second electrode away from the side surface of the base, wherein the third electrode is insulated from the second electrode;
wherein the susceptor is disposed in the reaction chamber;
wherein the method comprises:
S21: using the susceptor to support the substrate, and generating plasma in the reaction chamber to perform plasma processing on the substrate;
S22: after completing the plasma processing, maintaining the plasma in the reaction chamber, forming plasma on a side surface of the susceptor, and providing an adsorption electrode applied with a positive voltage at a bottom of the side surface of the susceptor;
S23: performing a top-down purge to weaken the plasma in the reaction chamber until the plasma is extinguished, while maintaining the plasma on the side surface of the susceptor, and maintaining the positive voltage on the adsorption electrode; and
S24: stopping a formation of the plasma on the side surface of the susceptor, applying a radio-frequency voltage to the adsorption electrode to form plasma on a surface of the adsorption electrode, maintaining the plasma on the surface of the adsorption electrode for a period of time, and maintaining the top-down purge during the period of time.
